(19) United States
(12) Patent Application Publication
(10) Pub. No.: US 2009/0230400 A1
(43) Pub. Date: Sep. 17, 2009

(54) THIN FILM TRANSISTOR AND FABRICATING METHOD THEREOF

(75) Inventors: Chia-Wen Chang, Taichung County (TW); Jiun-Jia Huang, Yunlin County (TW); Tzu-Heng Chang, Taipei County (TW); Tan-Fu Lei, Hsinchu City (TW); Szu-Fen Chen, Taoyuan (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: Chunghwa Picture Tubes, LTD., Taipei (TW)

(21) Appl. No.: 12/198,081

(22) Filed: Aug. 25, 2008

(30) Foreign Application Priority Data
Mar. 14, 2008 (TW) 97109139

(51) Int. Cl. H01L 21/336; H01L 29/786

(52) U.S. Cl. 257/66; 438/166; 257/E21.413; 257/E29.273

(57) ABSTRACT

A method for fabricating a thin film transistor is described. The method includes: providing a substrate; forming a sacrificial layer on the substrate; forming a polysilicon pattern layer on the substrate to surround the sacrificial layer; forming a gate insulation layer to cover at least the polysilicon pattern layer; forming a gate pattern on the gate insulation layer above the polysilicon pattern layer; forming a source region, a drain region, and an active region in the polysilicon pattern layer, wherein the active region is between the source region and the drain region; forming a passivation layer to cover the gate pattern and a portion of the gate insulation layer; forming a source conductive layer and a drain conductive layer on the passivation layer, wherein the source conductive layer and the drain conductive layer are electrically connected to the source region and the drain region of the polysilicon pattern layer respectively.

### CROSS-REFERENCE TO RELATED APPLICATION

This application claims the priority benefit of Taiwan application serial no. 97109139, filed on Mar. 14, 2008. The entirety of the above-mentioned patent application is hereby incorporated by reference herein and made a part of specification.

### BACKGROUND OF THE INVENTION

1. Field of the Invention

The present invention generally relates to a thin film transistor (TFT) and a fabricating method thereof, in particular, to a polysilicon TFT and a fabricating method thereof.

2. Description of Related Art

In a conventional low-temperature polysilicon thin film transistor (TFT), grain boundary defect in the channel thereof is the major factor for causing deterioration in device characteristics. This problem of grain boundary defect can be effectively resolved by reducing the size of the channel to nano level. Thus, how to fabricate nanowire (NW) channel has become one of the major research subjects in the industry.

Conventionally, a polysilicon material is patterned through electron beam lithography technique so as to form a NW channel. However, the cost of the electron beam lithography technique is very high and the production yield of the conventional method cannot be effectively improved. Thus, a technique for fabricating NW channel through etching process is adopted gradually. Generally speaking, self-aligned sidewall spacer is usually adopted along with the etching process for fabricating NW channel.

FIGS. 1A˜1D are cross-sectional views illustrating a NW channel fabricating process according to the conventional technique. Referring to FIG. 1A, first, a substrate 110 is provided, and a thermal oxide layer 112 is formed on the substrate 110. Then referring to FIG. 1B, a gate 114 is formed on the thermal oxide layer 112. Next, referring to FIG. 1C, a gate insulation layer 115 and a polysilicon material layer 116 are sequentially formed to cover the gate 114 and a portion of the thermal oxide layer 112. After that, referring to FIG. 1D, part of the polysilicon material layer 116 is removed through anisotropic etching, so as to form a NW channel 118 at both sides of the gate 114. It should be noted that since the height of the NW channel 118 is mainly determined by the height of the gate 114 and there is certain restriction on the size of the gate 114 so that the gate 114 cannot be reduced unlimited, the size of the NW channel 118 is directly limited by the size of the gate 114. Besides, the control capability of the gate 114 to the NW channel 118 cannot be improved effectively since only one side of the NW channel 118 is corresponding to the gate 114.

### SUMMARY OF THE INVENTION

Accordingly, the present invention is directed to a thin film transistor (TFT) having good device characteristics.

The present invention is directed to a method for fabricating a TFT, wherein a NW channel of desired size can be fabricated effectively.

The present invention provides a method for fabricating a TFT. First, a substrate is provided. Then, a sacrificial layer is formed on the substrate. Next, a polysilicon pattern layer is formed on the substrate to surround the sacrificial layer. After that, a gate insulation layer is formed to cover at least the polysilicon pattern layer. Besides, a gate pattern is formed on the gate insulation layer above the polysilicon pattern layer. Then, a source region, a drain region, and an active region are formed in the polysilicon pattern layer, wherein the active region is located between the source region and the drain region. In addition, a passivation layer is formed to cover a portion of the gate insulation layer and the gate pattern. After that, a source conductive layer and a drain conductive layer are formed on the passivation layer, wherein the source conductive layer and the drain conductive layer are electrically connected to the source region and the drain region in the polysilicon pattern layer respectively.

According to an embodiment of the present invention, a buffer layer is further formed on the substrate before the sacrificial layer is formed.

According to an embodiment of the present invention, the sacrificial layer is further removed before the gate insulation layer is formed.

According to an embodiment of the present invention, the step of forming the polysilicon pattern layer includes: forming an amorphous silicon pattern layer on the substrate and then performing a recrystallization process to the amorphous silicon pattern layer to form the polysilicon pattern layer.

According to an embodiment of the present invention, the recrystallization process includes solid phase crystallization.

According to an embodiment of the present invention, the recrystallization process includes metal-induced lateral crystallization.

According to an embodiment of the present invention, the recrystallization process includes laser crystallization.

According to an embodiment of the present invention, the passivation layer has a first contact window opening which exposes the gate pattern, and the passivation layer and the gate insulation layer have a second contact window opening and a third contact window opening which respectively expose the source region and the drain region. The source conductive layer is electrically connected to the source region through the second contact window opening, and the drain conductive layer is electrically connected to the drain region through the third contact window opening.

The present invention provides a TFT including a substrate, a polysilicon pattern layer, a gate insulation layer, a gate pattern, a passivation layer, a source conductive layer, and a drain conductive layer. The polysilicon pattern layer is disposed on the substrate. The polysilicon pattern layer has a source region, a drain region, and an active region. The active region is located between the source region and the drain region, and an opening is existed surrounded by the polysilicon pattern layer. The gate insulation layer covers at least the polysilicon pattern layer. The gate pattern is disposed on the gate insulation layer and is corresponding to the active region of the polysilicon pattern layer. The passivation layer covers a portion of the gate insulation layer and the gate pattern. The source conductive layer and the drain conductive layer are disposed on the passivation layer and are electrically connected to the source region and the drain region of the polysilicon pattern layer respectively.

According to an embodiment of the present invention, the TFT further includes a sacrificial layer disposed in the opening of the polysilicon pattern layer, and the gate insulation layer covers the sacrificial layer.

According to an embodiment of the present invention, the TFT further includes a buffer layer disposed between the substrate and the polysilicon pattern layer.

According to an embodiment of the present invention, the passivation layer has a first contact window opening which exposes the gate pattern, and the passivation layer and the gate insulation layer have a second contact window opening and a third contact window opening which respectively expose the source region and the drain region. The source conductive layer is electrically connected to the source region through the second contact window opening, and the drain conductive layer is electrically connected to the drain region through the third contact window opening.

In the TFT fabricating method provided by the present invention, the height of a polysilicon pattern layer is determined by using a sacrificial layer. Thus, according to the present invention, a polysilicon pattern layer of desired size can be fabricated by controlling the height of the sacrificial layer. In addition, the TFT in the present invention has very good device characteristics.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A˜1D are cross-sectional views illustrating a nanowire (NW) channel fabricating process according to the conventional technique.

FIGS. 2A˜2H are top views illustrating a thin film transistor (TFT) fabricating method according to a first embodiment of the present invention.

FIGS. 3A˜3H are cross-sectional views illustrating a TFT fabricating method according to the first embodiment of the present invention.

FIGS. 4A˜4D are top views illustrating a TFT fabricating method according to a second embodiment of the present invention.

FIGS. 5A˜5D are cross-sectional views illustrating a TFT fabricating method according to the second embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

### First Embodiment

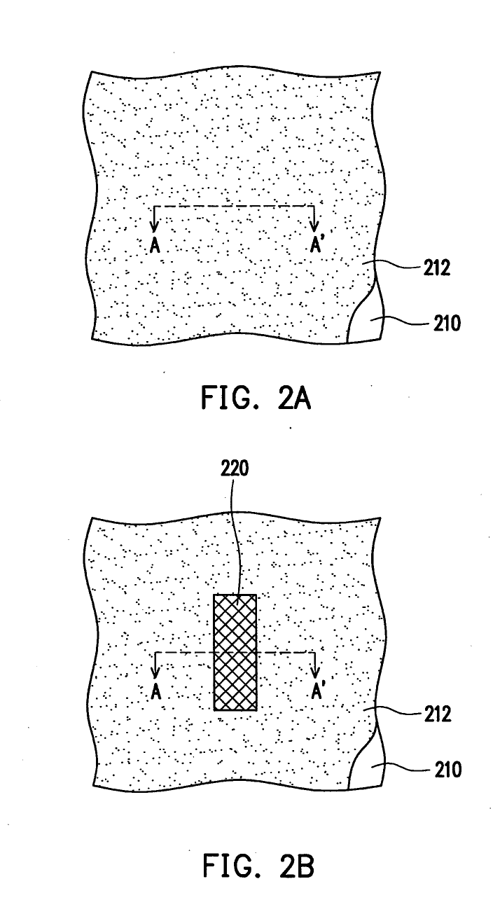

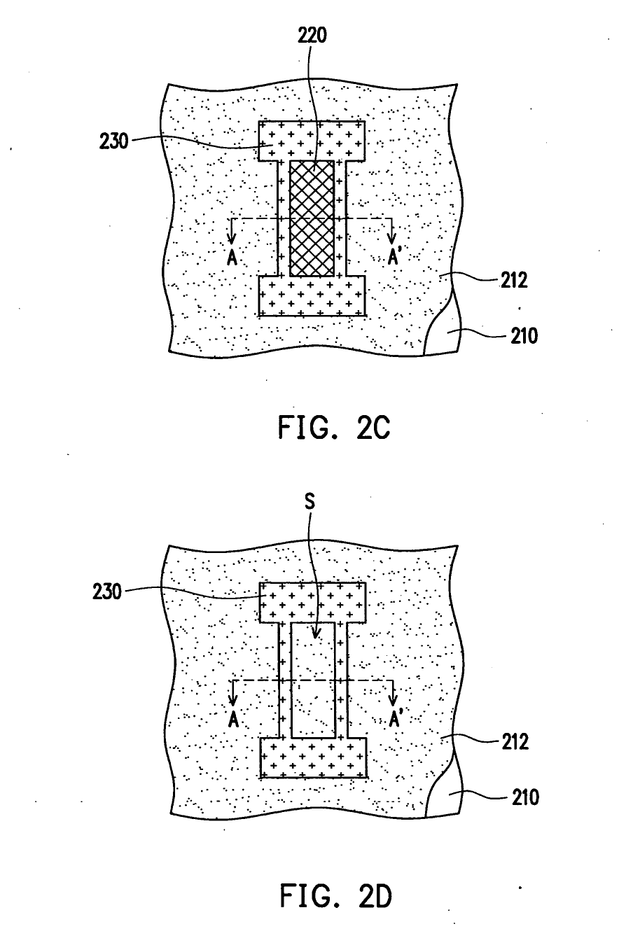

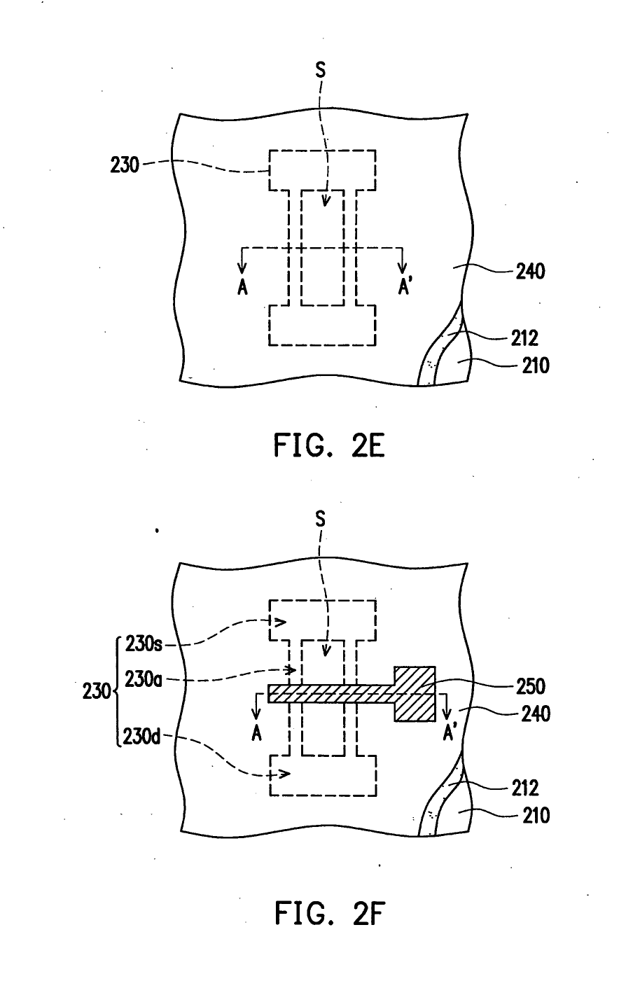

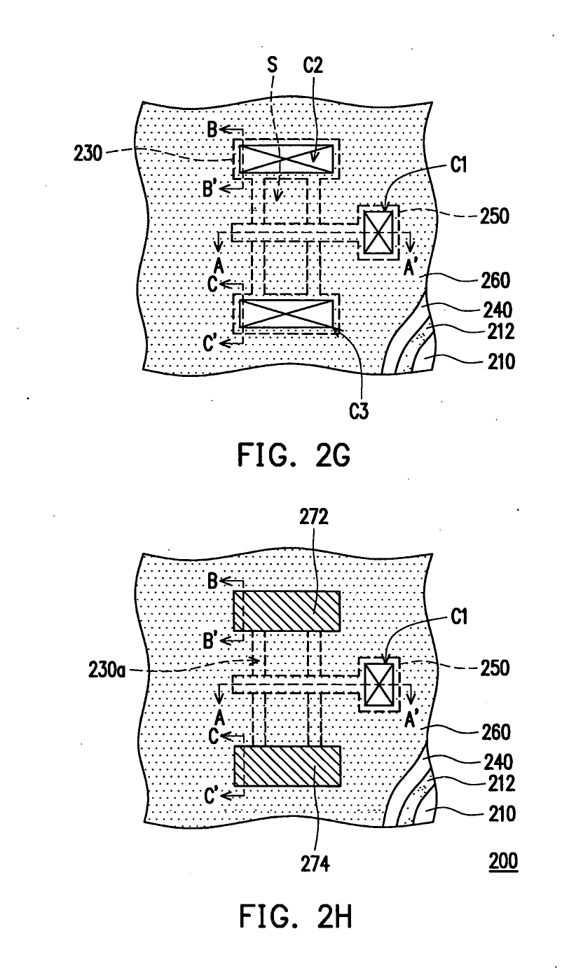

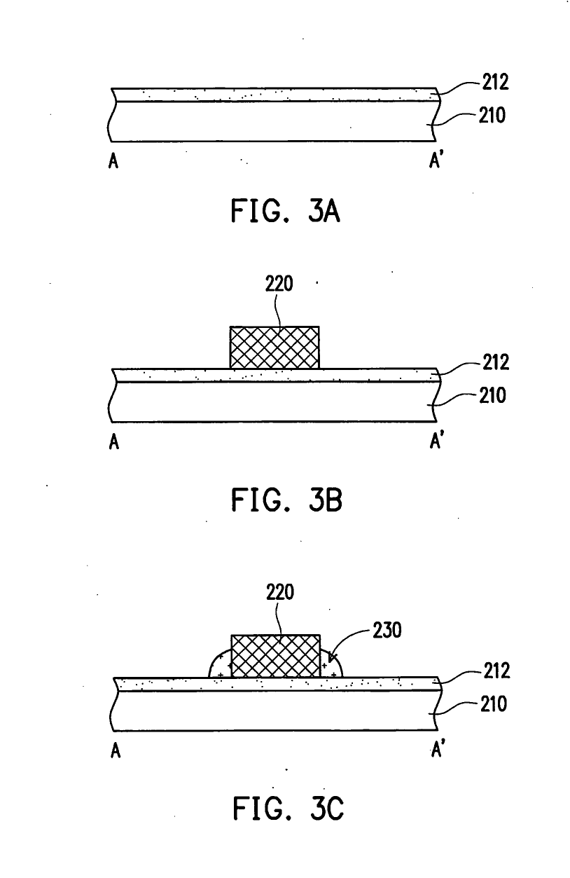

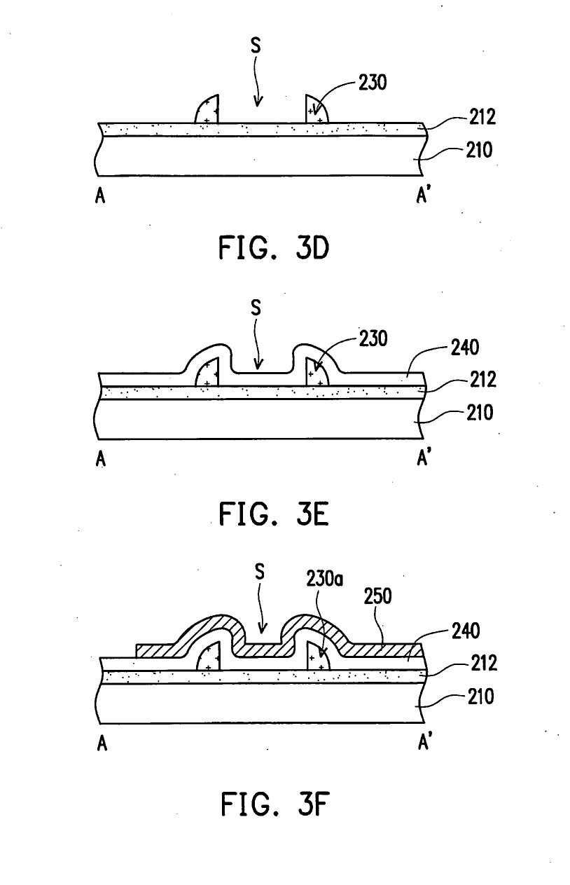

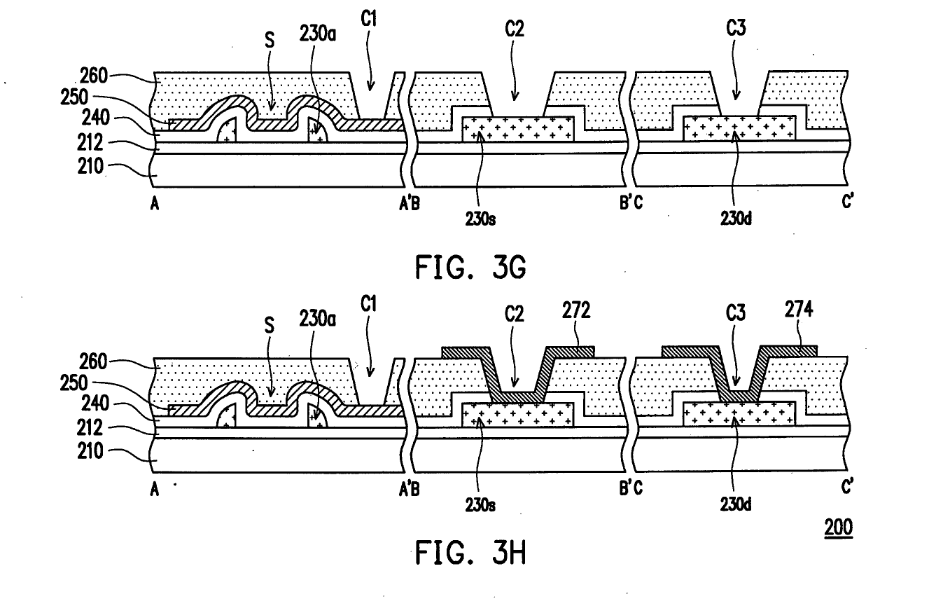

FIGS. 2A˜2H are top views illustrating a thin film transistor (TFT) fabricating method according to the first embodiment of the present invention, and FIGS. 3A˜3H are cross-sectional views illustrating a TFT fabricating method according to the first embodiment of the present invention. Referring to FIG. 2A and FIG. 3A, first, a substrate 210 is provided. Generally speaking, a buffer layer 212 may be selectively formed on the substrate 210 to assist the fabrication of subsequent layers. The material of the buffer layer 212 includes silicon oxide, silicon nitride, or silicon-oxy-nitride.

Then, referring to FIG. 2B and FIG. 3B, a sacrificial layer 220 is formed on the substrate 210. To be specific, the sacrificial layer 220 may be formed by depositing a material layer (not shown, the material thereof may be silicon oxide, silicon nitride, silicon-oxy-nitride, or metal) on the entire buffer layer 212 and then patterning the material layer through a mask process. However, the present invention is not limited thereto, and the height and pattern of the sacrificial layer 220 may be changed according to the actual requirement by those having ordinary skill in the art.

Next, referring to FIG. 2C and FIG. 3C, a polysilicon pattern layer 230 is formed on the buffer layer 212 on the substrate 210 to surround the sacrificial layer 220. According to an embodiment of the present invention, the method for forming the polysilicon pattern layer 230 includes following steps. First, an amorphous silicon material layer is deposited on the entire buffer layer 212 to cover the sacrificial layer 220 through chemical vapour deposition (CVD). Then, the amorphous silicon material layer is patterned to form an amorphous silicon pattern layer. The amorphous silicon material layer may be patterned through dry etching, wherein oxygen or a C—F based gas may be used as a reactive gas source and a bias may be supplied to the reactive gas source to form plasma for anisotropically etching the amorphous silicon material layer, so as to form an amorphous silicon pattern layer of desired shape. Next, a recrystallization process is performed to the amorphous silicon pattern layer to form a polysilicon pattern layer 230. The recrystallization process is not limited in the present invention and which may be solid phase crystallization, metal-induced lateral crystallization, or laser crystallization.

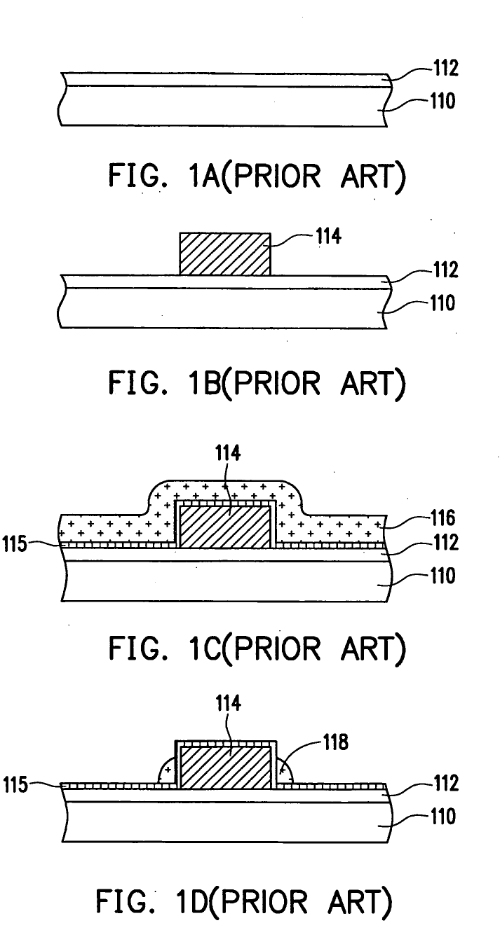

In particular, the size of the polysilicon pattern layer 230 formed at both sides of the sacrificial layer 220 is determined by the height of the sacrificial layer 220. In other words, the size of the polysilicon pattern layer 230 located at both sides of the sacrificial layer 220 can be adjusted according to the actual requirement. As shown in FIG. 1D, since conventionally there is certain restriction on the size of the gate 114, the size of the nanowire (NW) channel 118 is limited by the size of the gate 114. While in the TFT fabricating method provided by the present invention, the size of the NW channel 118 can be further reduced and accordingly grain boundary defects can be effectively avoided.

Thereafter, referring to FIG. 2D and FIG. 3D, in an embodiment of the present invention, the sacrificial layer 220 can be selectively removed to form an opening S in the polysilicon pattern layer 230 before subsequent layers are formed. That is, after the sacrificial layer 220 is removed, the opening S is formed and the opening S is surrounded by the polysilicon pattern layer 230. However, the sacrificial layer 220 may also be retained, as described in the second embodiment.

Next, referring to FIG. 2E and FIG. 3E, a gate insulation layer 240 is formed to cover the polysilicon pattern layer 230. The material of the gate insulation layer 240 may be silicon oxide (SiO) formed by using silicon nitride (SiN) or tetraethoxy silane (TEOS) as a reactive gas source.

Next, referring to FIG. 2F and FIG. 3F, a gate pattern 250 is formed on the gate insulation layer 240 above the polysilicon pattern layer 230. The gate pattern 250 may be formed with following steps. First, a metal material is deposited on the gate insulation layer 240 through physical vapour deposition (PVD). The metal material is then patterned through a mask process to form the desired gate pattern 250. Foregoing metal material may be a low-resistance material such as Al, Au, Cu, Mo, Cr, Ti, Al alloy, Al-Mg alloy, or Mo alloy. Thereafter, an ion doping process is performed to the polysilicon pattern layer 230 to form the source region 230s and the drain region 230d at the opposite two ends of the polysilicon pattern layer 230, and the region between the source region 230s and the drain region 230d is the active region 230a.

After that, referring to FIG. 2G and FIG. 3G, a passivation layer 260 is formed to cover a portion of the gate insulation layer 240 and the gate pattern 250. The passivation layer 260 has a first contact window opening C1 which exposes the gate pattern 250. In addition, the passivation layer 260 and the gate insulation layer 240 have a second contact window opening C2 and a third contact window opening C3 which respectively expose the source region 230s and the drain region 230d.

Additionally, referring to FIG. 2H and FIG. 3H, a source conductive layer 272 and a drain conductive layer 274 are formed on the passivation layer 260. The source conductive layer 272 and the drain conductive layer 274 are electrically connected to the source region 230s and the drain region 230d respectively through the second contact window opening C2 and the third contact window opening C3. By now, the fabricating process of the TFT 200 in the present invention is completed.

According to the present invention, the polysilicon pattern layer 230 in the TFT 200 is patterned through dry etching. Thereby, the production yield can be increased and the fabricating cost can be reduced. As shown in FIG. 3H, all surfaces of the polysilicon pattern layer 230 of the active region 230a are corresponding to the gate pattern 250 except the bottom surface thereof, and as a result, the TFT 200 in the present invention has good channel control capability.

### Second Embodiment

The second embodiment is similar to the first embodiment, and the difference between the two is that in the present embodiment, the sacrificial layer is not removed. The initial steps of the TFT fabricating method in the second embodiment are the same as those illustrated in FIGS. 2A˜2C and FIGS. 3A˜3C therefore will not be described herein.

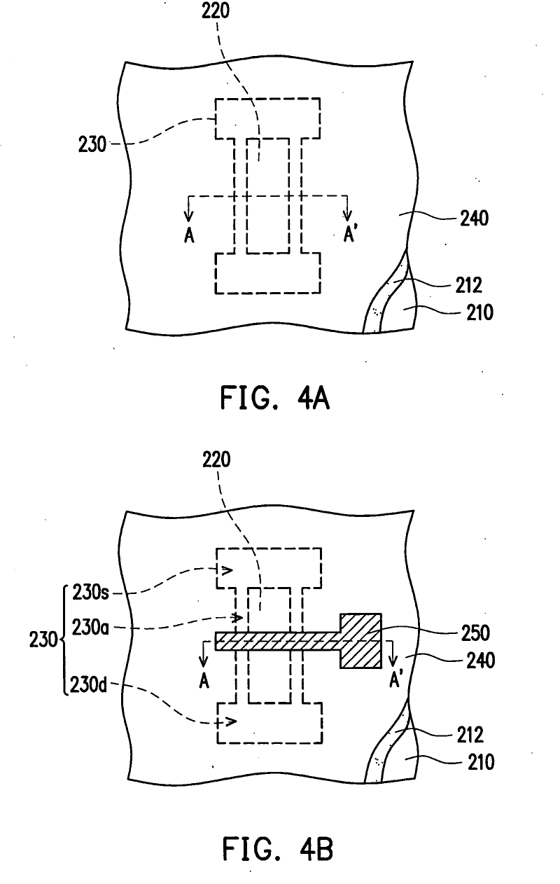

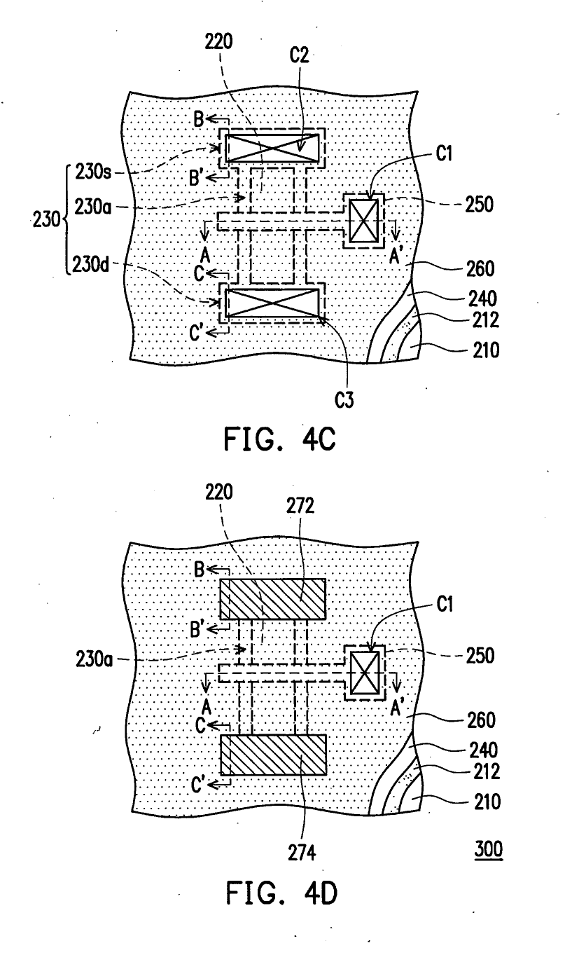

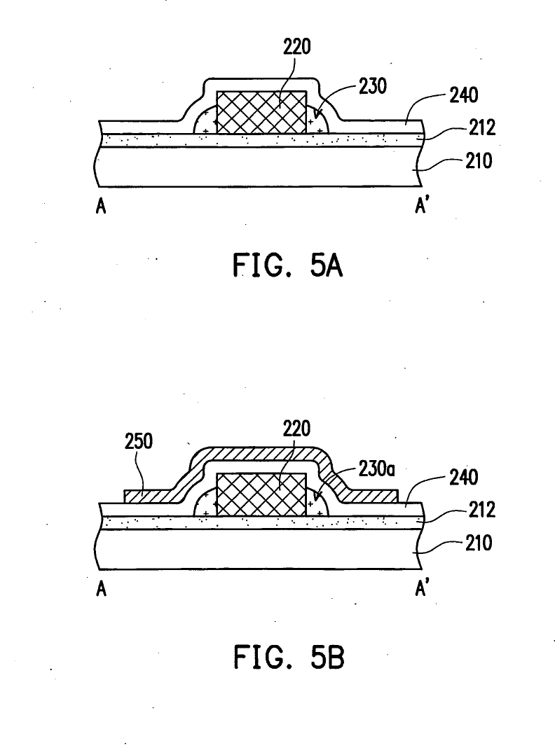

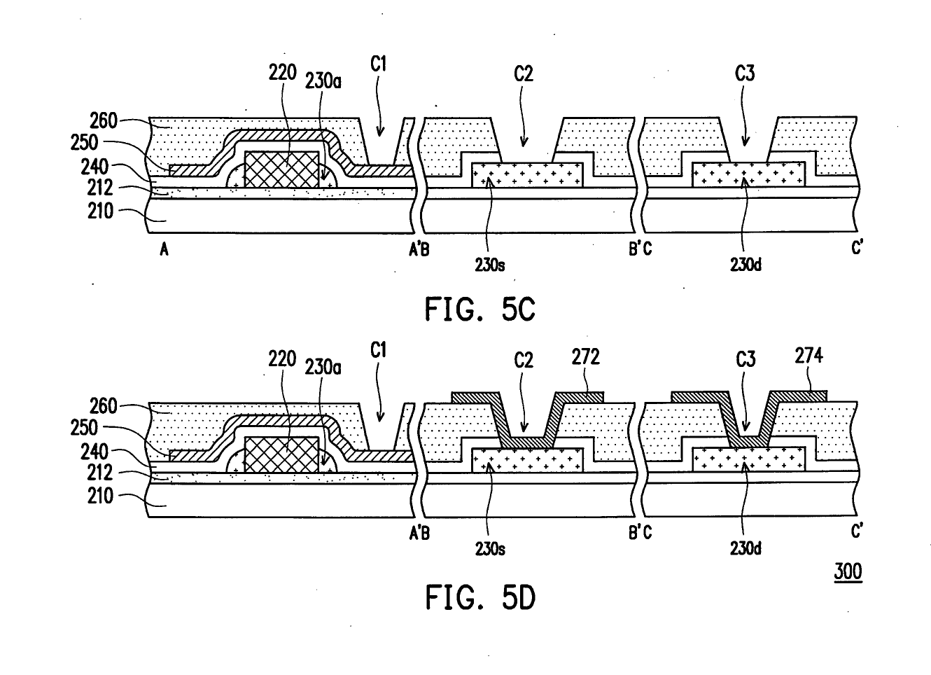

Then referring to FIG. 4A and FIG. 5A, a gate insulation layer 240 is formed to cover the polysilicon pattern layer 230 and the sacrificial layer 220. The material of the gate insulation layer 240 may be SiO formed by using SiN or TEOS as a reactive gas source.

Next, referring to FIG. 4B and FIG. 5B, a gate pattern 250 is formed on the gate insulation layer 240 above the polysilicon pattern layer 230. The gate pattern 250 may be formed by depositing a metal material or a polysilicon material on the gate insulation layer 240 through PVD and then patterning the metal material or polysilicon material through a mask process. The metal material may be a low-resistance material such as Al, Au, Cu, Mo, Cr, Ti, Al alloy, Al-Mg alloy, or Mo alloy. After that, an ion doping process is performed to the polysilicon pattern layer 230 to form the source region 230s and the drain region 230d at the opposite two ends of the polysilicon pattern layer 230, and the region between the source region 230s and the drain region 230d is the active region 230a.

Thereafter, referring to FIG. 4C and FIG. 5C, a passivation layer 260 is formed to cover a portion of the gate insulation layer 240 and the gate pattern 250. The passivation layer 260 has a first contact window opening C1 which exposes the gate pattern 250. In addition, the passivation layer 260 and the gate insulation layer 240 have a second contact window opening C2 and a third contact window opening C3 which respectively expose the source region 230s and the drain region 230d.

Next, referring to FIG. 4D and FIG. 5D, a source conductive layer 272 and a drain conductive layer 274 are formed on the passivation layer 260. The source conductive layer 272 and the drain conductive layer 274 are electrically connected to the source region 230s and the drain region 230d respectively through the second contact window opening C2 and the third contact window opening C3. By now, the fabrication of the TFT 300 in the present embodiment is completed.

In overview, in the TFT fabricating method provided by the present invention, the height of the polysilicon pattern layer is determined by using a sacrificial layer. Thereby, according to the present invention, a polysilicon pattern layer of desired size can be fabricated according to the actual requirement. Moreover, according to the present invention, the polysilicon pattern layer is fabricated through dry etching. As a result, the production yield can be effectively increased and the fabricating cost can be reduced. Furthermore, the TFT in the present invention has very good device characteristics.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A fabricating method of a thin film transistor (TFT), comprising:
providing a substrate;
forming a sacrificial layer on the substrate;
forming a polysilicon pattern layer on the substrate to surround the sacrificial layer;
forming a gate insulation layer to cover at least the polysilicon pattern layer;
forming a gate pattern on the gate insulation layer above the polysilicon pattern layer;
forming a source region, a drain region, and an active region in the polysilicon pattern layer, wherein the active region is located between the source region and the drain region;
forming a passivation layer to cover a portion of the gate insulation layer and the gate pattern; and
forming a source conductive layer and a drain conductive layer on the passivation layer, wherein the source conductive layer and the drain conductive layer are electrically connected to the source region and the drain region of the polysilicon pattern layer respectively.

2. The fabricating method according to claim 1 further comprising forming a buffer layer on the substrate before forming the sacrificial layer.

3. The fabricating method according to claim 1 further comprising removing the sacrificial layer before forming the gate insulation layer.

4. The fabricating method according to claim 1, wherein the step of forming the polysilicon pattern layer comprises:
forming an amorphous silicon pattern layer on the substrate; and
performing a recrystallization process to the amorphous silicon pattern layer to form the polysilicon pattern layer.

5. The fabricating method according to claim 4, wherein the recrystallization process comprises solid phase crystallization.

6. The fabricating method according to claim 4, wherein the recrystallization process comprises metal-induced lateral crystallization.

7. The fabricating method according to claim 4, wherein the recrystallization process comprises laser crystallization.

8. The fabricating method according to claim 1, wherein the passivation layer has a first contact window opening for exposing the gate pattern, the passivation layer and the gate insulation layer have a second contact window opening and a third contact window opening for respectively exposing the source region and the drain region, the source conductive layer is electrically connected to the source region through the second contact window opening, and the drain conductive layer is electrically connected to the drain region through the third contact window opening.

9. The fabricating method according to claim 1, wherein the size of the polysilicon pattern layer formed at both sides of the sacrificial layer is determined by the height of the sacrificial layer.

10. A TFT, comprising:
a substrate;
a polysilicon pattern layer, disposed on the substrate, the polysilicon pattern layer having a source region, a drain region, and an active region, wherein the active region is located between the source region and the drain region, and an opening is existed surrounded by the polysilicon pattern layer;
a gate insulation layer, covering at least the polysilicon pattern layer;
a gate pattern, disposed on the gate insulation layer, wherein the gate pattern is corresponding to the active region of the polysilicon pattern layer;
a passivation layer, covering a portion of the gate insulation layer and the gate pattern; and
a source conductive layer and a drain conductive layer, disposed on the passivation layer, wherein the source conductive layer and the drain conductive layer are electrically connected to the source region and the drain region of the polysilicon pattern layer respectively.

11. The TFT according to claim 10 further comprising a sacrificial layer disposed in the opening surrounded by the polysilicon pattern layer, wherein the gate insulation layer covers the sacrificial layer.

12. The TFT according to claim 11, wherein the size of the polysilicon pattern layer formed at both sides of the sacrificial layer is determined by the height of the sacrificial layer.

13. The TFT according to claim 10 further comprising a buffer layer disposed between the substrate and the polysilicon pattern layer.

14. The TFT according to claim 10, wherein the passivation layer has a first contact window opening for exposing the gate pattern, the passivation layer and the gate insulation layer have a second contact window opening and a third contact window opening for respectively exposing the source region and the drain region, the source conductive layer is electrically connected to the source region through the second contact window opening, and the drain conductive layer is electrically connected to the drain region through the third contact window opening.
